(19) United States
(12) Patent Application Publication
(10) Pub. No.: US 2025/0299715 A1
(43) Pub. Date: Sep. 25, 2025

(54) RESISTIVE MEMORY DEVICE CAPABLE OF INCREASING MEMORY CAPACITY

(71) Applicant: SAMSUNG ELECTRONICS CO., LTD., Suwon-si (KR)

(72) Inventors: Gyuseong KANG, Suwon-si (KR); Sanggyeong WON, Suwon-si (KR); Junsuk LEE, Suwon-si (KR)

(73) Assignee: SAMSUNG ELECTRONICS CO., LTD., Suwon-si (KR)

(21) Appl. No.: 18/793,256

(22) Filed: Aug. 2, 2024

(30) Foreign Application Priority Data
Mar. 19, 2024 (KR) 10-2024-0337688

(51) Int. Cl. G11C 11/16

(52) U.S. Cl. CPC G11C 11/1655; G11C 11/1657

(57) ABSTRACT

A resistive memory device that comprises a data cell array including a plurality of memory cells, each column of the plurality of memory cells having an electrically separated first bit line and a second bit line; a row decoder configured to decode a row address and select one or more word lines of the plurality of memory cells in response to the row address; and a column decoder configured to decode a column address and select one of the first bit line and the second bit line in response to the row address decoded by the row decoder and the column address, wherein the first bit line comprises a first metal layer, and the second bit line comprises the first metal layer and a second metal layer.

### CROSS-REFERENCE TO RELATED APPLICATIONS

This application claims priority under 35 U.S.C. § 119 to Korean Patent Application No. 10-2024-0037688 filed on Mar. 19, 2024, in the Korean Intellectual Property Office, the disclosures of which are incorporated by reference herein in their entireties.

### BACKGROUND

### 1. Field

Embodiments of the present disclosure described herein relates to a semiconductor memory device, and more specifically, to a resistive memory device capable of securing a read margin even when the number of word lines is increased.

### 2. Description of Related Art

Semiconductor memory devices may be broadly divided into volatile memory and non-volatile memory. Volatile memory (e.g., DRAM or SRAM) has fast reading and writing speeds, but stored data is lost when the power supply is cut off. In one or more examples, non-volatile memory (e.g., MRAM or Flash memory) may preserve data even if the power supply is interrupted.

The memory cell of magnetic random access memory MRAM includes a magnetic tunnel junction MTJ element whose resistance changes depending on data and an access transistor. The write operation of MRAM is performed by activating an access transistor through the word line and applying a large current so that the data of the MTJ element can change. The value of data recorded in the MTJ element varies depending on the direction of the current.

Due to the read/write structure of the MTJ element that uses current, as the number of word lines in the MRAM increases, the difference in leakage current or metal loading between memory cells (e.g., near cells and far cells) increases. Therefore, as the number of word lines increases, read and write margins of MRAM deteriorate. This decline in read margin worsens as the number of word lines increases, thereby acting as a barrier to increasing the memory capacity of MRAM.

### SUMMARY

Embodiments of the present disclosure provides a resistive memory device that can reduce differences in leakage current or metal load between memory cells. Another object of the present embodiments is to provide a resistive memory device capable of increasing capacity and reducing read margin degradation even when the number of word lines is increased.

According to an aspect of the disclosure, a resistive memory device, comprises: a data cell array comprising a plurality of memory cells, each column of the plurality of memory cells having an electrically separated first bit line and a second bit line; a row decoder configured to decode a row address and select one or more word lines of the plurality of memory cells in response to the row address; and a column decoder configured to decode a column address and select one of the first bit line and the second bit line in response to the row address decoded by the row decoder and the column address, wherein the first bit line comprises a first metal layer, and the second bit line comprises the first metal layer and a second metal layer.

According to an aspect of the disclosure, a resistive memory device, comprises: a data cell array comprising a plurality of memory cells connected to one or more word lines; a reference cell array sharing the one or more word lines with the data cell array; a row decoder configured to decode a row address and select one of the one or more word lines in response to the row address; and a column decoder configured to decode a column address and select a data bit line of the data cell array and a reference bit line of the reference cell array in response to the column address, wherein the reference bit line comprises a lower metal layer of a magnetic tunnel junction and an upper metal layer of the magnetic tunnel junction.

According to an aspect of the disclosure, a resistive memory device, comprises: a first data cell array connected to a first word line group and a first bit line group; a second data cell array connected to a second word line group and a second bit line group, the second data cell array sharing a column with the first data cell array; a reference cell array connected to the first word line group and the second word line group; a row decoder configured to decode a row address and select a word line of the first word line group and the second word line group in response to the row address; and a column decoder configured to decode a column address and select a bit line from one of the first bit line group and the second bit line group in response to the row address and the column address, wherein the column decoder selects the first bit line group based on the row address corresponding to the first word line group, and selects the second bit line group based on the row address corresponding to the second word line group.

### BRIEF DESCRIPTION OF THE FIGURES

The above and other objects and features of the present disclosure will become apparent by describing in detail embodiments thereof with reference to the accompanying drawings.

FIG. 1 is a block diagram showing a resistive memory device according to one or more embodiments.

FIG. 2 is a diagram showing an example configuration of the data cell array and the reference cell array of FIG. 1, according to one or more embodiments.

FIG. 3 is a diagram showing how data is written into the memory cell MC of FIG. 2, according to one or more embodiments.

FIG. 4 is a diagram showing the configuration and connection relationship of memory cells included in a data cell array, according to one or more embodiments.

FIG. 5 is a diagram showing the structure of the memory cell shown in FIG. 4, according to one or more embodiments.

FIG. 6 is a diagram briefly showing the circuit structure of a reference cell, according to one or more embodiments.

FIG. 7 is a block diagram showing a method of connecting the first bit line BLx and the second bit line BLy of the first and second data cell arrays shown in FIG. 1, according to one or more embodiments.

FIG. 8 is a cross-sectional view briefly showing a cross-section of the data cell array taken along the cutting line A-A′ of FIG. 7, according to one or more embodiments.

FIG. 9 is a block diagram showing a method of connecting the reference bit line R_BL and the reference source line R_SL of the reference cell array shown in FIG. 1, according to one or more embodiments.

FIG. 10 is a cross-sectional view briefly showing a cross-section of the reference cell array taken along the cutting line (A-A′) of FIG. 9, according to one or more embodiments.

FIG. 11 is a graph showing the effect of the embodiments of the present disclosure.

FIG. 12 shows the difference in resistance values between the memory cell MC and the reference cell RC of FIG. 11 when the embodiments of the present disclosure are applied and when the embodiments of the present disclosure are not applied.

### DETAILED DESCRIPTION

It is to be understood that both the foregoing general description and the following detailed description are exemplary, and it is to be considered that an additional description of the claimed embodiments is provided. Reference signs are indicated in detail in preferred embodiments of the present embodiments, examples of which are indicated in the reference drawings. Wherever possible, the same reference numbers are used in the description and drawings to refer to the same or like parts.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

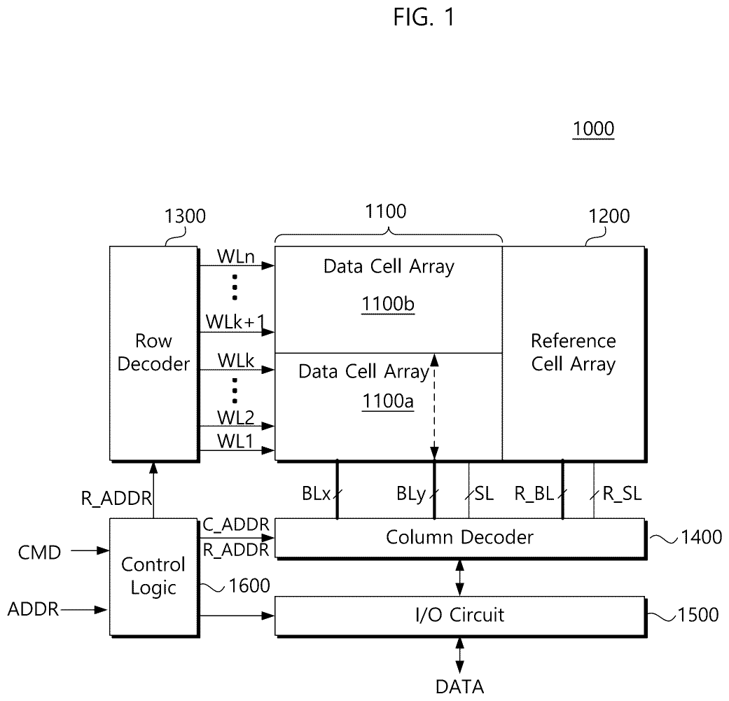

FIG. 1 is a block diagram showing a resistive memory device according to one or more embodiments of the present disclosure. Referring to FIG. 1, the resistive memory device 1000 may include a data cell array 1100, a reference cell array 1200, a row decoder 1300, a column decoder 1400, an input/output circuit 1500, and a control logic 1600.

The data cell array 1100 may include a plurality of bit cells that store data. Each of the plurality of bit cells included in the data cell array 1100 may be placed at a point where a plurality of word lines WL1 to WLn, a plurality of bit lines (BLx, BLy), and a source line SL intersect. For example, each of the bit cells may be connected to a corresponding word line among the plurality of word lines WL1 to WLn. Each of the bit cells may also be connected to a corresponding bit line and source line among the plurality of bit lines (BLx, BLy) and source lines SL. Bit cells can be selected by the word line voltage provided to the selected word line. In one or more examples, each bit cell may include an access transistor and a magnetic tunnel junction MTJ element. Through the bit line or source line, data can be stored in the selected bit cell or stored data can be sensed. In one or more examples, a first distance between the first data cell array 1100a and the column decoder 1400 is less than a second distance between the second data cell array 1100b and the column decoder 1400.

In one or more examples, each of the bit cells may be a magnetic random access memory MRAM element, such as STT-MRAM (Spin-Transfer Torque Magnetic Random Access Memory), Spin-RAM (Spin Torque Transfer Magnetization Switching RAM), and SMT-RAM (Spin Momentum Transfer). Alternatively, each of the bit cells may include a device configuration such as, but not limited to, phase change random access memory PRAM and ferroelectric random access memory FRAM. As understood by one of ordinary skill in the art, an MRAM may a non-volatile random access memory storing data in magnetic domains. For example, the MRAM may store data using magnetic storage elements. The magnetic storage element may be a MTJ element that includes two ferromagnetic plates, each of which can hold a magnetization, separated by a thin insulating layer. One of the two plates is a permanent magnet set to a particular polarity; the other plate's magnetization can be changed to match that of an external field to store memory.

In one or more examples, the data cell array 1100 may be divided into a first data cell array 1100a and a second data cell array 1100b according to the connected word lines WL1 to WLk, and WLk+1 to WLn. The first data cell array 1100a includes a plurality of memory cells connected to word lines WL1 to WLk (e.g., ‘k’ is an integer greater than 1). The second data cell array 1100b includes a plurality of memory cells connected to word lines WLk+1 to WLn(‘n’ is an integer greater than 1). For example, ‘k’ may be ‘512’ and ‘n’ may be ‘1024’. For example, the first data cell array 1100a and the second data cell array 1100b may each be provided in a structure that divides the total number of word lines. However, it will be well understood that the number of word lines connected to the first data cell array 1100a and the second data cell array 1100b is not limited to the disclosure herein, and may be adjusted or changed according to various purposes. As understood by one of ordinary skill in the art, data cell array 1100 may include more than two data cell arrays. In one or more examples, the first data cell array 1100a and the second data cell array 1100b may include a same number of word lines. In one or more examples, the second data cell array 1100b may include a different number of word lines. In one or more examples, the word lines of the first data cell array 1100a and the second data cell array 1100b may be equally spaced apart. In one or more examples, a first spacing between first and second word lines may be different than a second spacing between third and fourth word lines. In one or more examples, the bit lines in the data cell array 1100 may be equally spaced apart. In one or more examples, a first spacing between first and second bit lines may be different than a second spacing between third and fourth bit lines.

The first data cell array 1100a may be connected to the first bit lines BLx. The second data cell array 1100b may be connected to the second bit lines BLy. Each of the first bit lines BLx may be connected to memory cells of the first data cell array 1100a using one metal layer. The metal layer for forming the bit lines (BLx, BLy) may be located on top of the MTJ. Therefore, in one or more examples, when there are two metal layers for forming the bit lines BLx and BLy, the first bit line BLx may use the metal layer located in the lower of the two metal layers formed on the MTJ.

In one or more examples, each of the second bit lines BLy is bypassed to the second data cell array 1100b without being electrically connected to the memory cells of the first data cell array 1100a. In one or more examples, each of the second bit lines BLy may be formed using the upper metal layer of the two metal layers formed on the MTJ in the first data cell array 1100a area. In one or more examples, each of the second bit lines BLy may be connected to memory cells in the second data cell array 1100b area using two upper and lower metal layers. In one or more examples, the method of forming the source line SL in the first data cell array 1100a and the second data cell array 1100b may be the same.

According to one or more embodiments, the reference cell array 1200 may include a plurality of reference cells. Reference cells may be used to determine the value stored in the data cell. For example, data cells of the data cell array 1100 and reference cells of the reference cell array 1200 may be connected to one word line (e.g., WL2). When the word line WL2 may be activated, data cells and reference cells connected to the word line WL2 can be selected simultaneously.

A plurality of reference cells RC connected to one column may share one or more reference bit lines R_BL and a reference source line R_SL, and a plurality of word lines WL1 to WLk and WLk+1 to WLn can be selected mutually exclusively. The reference cell RCi selected by the word line (e.g., for WLi, ‘i’ is a positive integer less than or equal to ‘n’) is in the same environment (e.g., the path along which the read current flows) as the memory cell MCi selected by the same word line (WLi). Accordingly, the error for reading the value stored in the memory cell MCi can be advantageously reduced. Each of the plurality of reference cells RC may include an access transistor. However, each of the plurality of reference cells RC may not include an MTJ element compared to the memory cell MC. In this way, a reference cell in which the MTJ element is omitted may be referred to as a short cell. Additionally, the reference source line R_SL of each of the plurality of reference cells RC may be connected to a reference resistor during a read operation.

In one or more examples, the reference bit line R_BL connected to the reference cell of the reference cell array 1200 may be formed using a metal layer located at the bottom of the MTJ for a short cell structure. In this case, the resistance of the bit line of the data cell array 1100 using the top metal layer of the MTJ may be different. Due to these characteristics, load matching does not occur in practice, which reduces the read margin of the data cell. The reference bit line R_BL connected to the reference cell of the present embodiments can be formed using an unused floating metal layer located on top of the MTJ. For example, the metal layer located on top of the MTJ and the metal layer formed on the bottom of the existing MTJ can be connected to each other at the edge of the cell array using vias or contacts. In this case, a reference bit line R_BL in which metal layers are connected in parallel at the top and bottom of the MTJ may be formed in the reference cell. The metal resistance of the reference cell can be reduced through the reference bit line R_BL structure in which two metal layers are connected in parallel. Therefore, the problem of the reference cell not matching the load with the data cell due to the relatively large metal resistance can be advantageously solved.

The row decoder 1300 decodes the row address R_ADDR and selects one of the plurality of word lines WL1 to WLn according to the decoding result. During a write operation or a read operation, the row decoder 1300 may transfer the word line voltage to any one word line selected by the row address R_ADDR. The access transistor of the memory cell selected by the row decoder 1300 may be turned on.

The column decoder 1400 may be connected to the data cell array 1100 through first bit lines BLx, second bit lines BLy, and source line SL. In one or more examples, the column decoder 1400 may be connected to the first data cell array 1100a through the first bit lines BLx. The column decoder 1400 may be connected to the second data cell array 1100b through the second bit lines BLy. In one or more examples, the column decoder 1400 may be connected to both the first data cell array 1100a and the second data cell array 1100b through the source line SL. In one or more examples, the column decoder 1400 may be connected to the reference cells of the reference cell array 1200 through the reference bit line R_BL and the reference source line R_SL.

The column decoder 1400 may select the first bit lines BLx, the second bit lines BLy, or the source line SL in response to the address ADDR provided from the control logic 1600. For example, the column decoder 1400 selects the first bit lines BLx when the row address R_ADDR corresponds to the word lines WL1 to WLk corresponding to the first data cell array 1100a. One of the first bit lines BLx can be selected by the column address C_ADDR. The column decoder 1400 selects the second bit lines BLy when the row address R_ADDR corresponds to the word lines WLk+1 to WLn corresponding to the second data cell array 1100b. One of the second bit lines BLy can be selected by the column address C_ADDR. In one or more examples, the column decoder 1400 may select the reference bit line R_BL or the reference source line R_SL in response to the column address C_ADDR provided from the control logic 1600.

The input/output circuit 1500 may be connected to the column decoder 1400 through data lines, and exchanges data with the outside through the input/output circuit 1500. During a program operation, the input/output circuit 1500 may receive write data from the input/output circuit 1500 and write it to the selected memory cell. During a read operation, the input/output circuit 1500 may sense a selected memory cell of the cell array 1100 and output the sensed data to the input/output circuit 1500. In one or more examples, the input/output circuit 1500 may include a write driver or a sense amplifier. The write driver may write write data to the selected memory cell. The write driver can provide program current or program voltage to the data line. The sense amplifier can read data stored in the selected memory cell by detecting the difference between the voltage of the source line SL and the reference voltage during a read operation.

In one or more examples, the input/output circuit 1500 can exchange data DATA with an external device (e.g., a memory controller). For example, during the write operation, the input/output circuit 1500 may transfer data DATA received from an external device to the write driver of the input/output circuit 1500. During the read operation, the input/output circuit 1500 may output read data transmitted from the sense amplifier of the input/output circuit 1500 to an external device.

The control logic 1600 receives control signals including a command CMD, an address ADDR, and a clock signal from an external device (e.g., a host or CPU) of the memory device 1000. The control logic 1600 may control the operation of the memory device 1000 based on a command or address received from an external device. The control logic 1600 can extract the row address R_ADDR from the received address ADDR and transmit it to the row decoder 1300 and the column decoder 1400, and transmit the column address C_ADDR to the column decoder 1400.

According to the above description, according to one or more embodiments, the data cell array 1100 includes the first data cell array 1100a using one metal layer as the first bit line BLx and the second data cell array 1100b using two metal layers as a second bit line BLy. Selection of bit lines (BLx, BLy) may be determined according to the position of the word line or row address. Using this structure, leakage current during the read operation can be reduced by reducing the number of memory cells connected per bit line. Therefore, read margin can be increased through the data cell array 1100 structure of the present embodiments.

In one or more examples, the reference bit line R_BL of the reference cell array 1200 may be formed using an unused floating metal layer located on top of the MTJ. The metal resistance of the reference cell can be advantageously reduced through the reference bit line R_BL structure, which has a parallel connection structure of two metal layers. Accordingly, the problem that the reference cell does not match the load with the data cell due to the relatively large metal resistance can be solved.

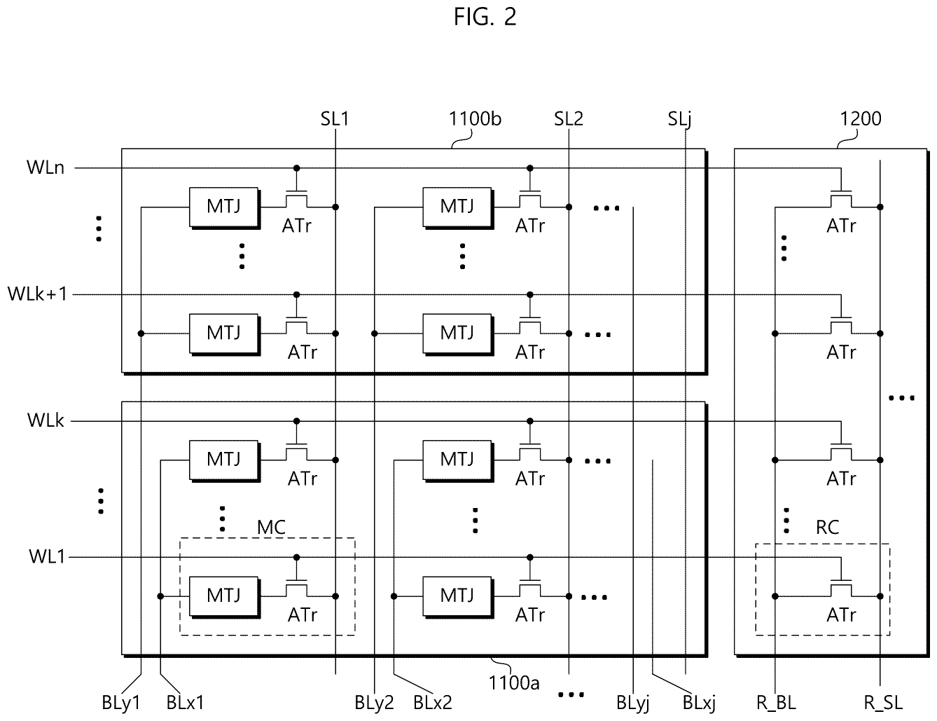

FIG. 2 is a diagram showing an example configuration of a data cell array and a reference cell array of FIG. 1. Referring to FIG. 2, the data cell array 1100 may be divided into a first data cell array 1100a and a second data cell array 1100b. Additionally, the reference cell array 1200 that shares a word line with the first data cell array 1100a and a word line with the second data cell array 1100b may be included.

The data cell array 1100 may include a plurality of memory cells MCs arranged along row and column directions. Illustratively, among the plurality of memory cells, one memory cell MC included in the first data cell array 1100a is indicated by a dotted box. Each memory cell MC may include an MTJ element and an access transistor ATr. As the MTJ elements constituting each memory cell MC may be programmed to have a specific resistance value, data corresponding to the specific resistance value can be stored in each memory cell MC.

Memory cells of the first data cell array 1100a may be connected to word lines WL1 to WLk, first bit lines BLx1 to BLxj, and source lines SL1 to SLj. One end of each of the MTJ elements may be connected to the first bit lines BLx1 to BLxj, and the other end of each MTJ element may be connected to one end of the access transistor ATr. The other end of the access transistor ATr may be connected to the source lines SL1 to SLj, and the gate electrode of the access transistor ATr may be connected to the word lines WL1 to WLk. The word line voltage of a memory cell selected by the row decoder 1300 among the plurality of memory cells is applied. Then, when the access transistor ATr is turned on by the word line voltage, the MTJ element is in a parallel state P depending on the direction of the current applied through one of the first bit lines BLx and the source line SL. In one or more examples, the MTJ element may be programmed in an anti-parallel state AP. In particular, the first bit lines BLx1 to BLxj are connected to the MTJ elements using only one metal layer.

Memory cells of the second data cell array 1100b may be connected to word lines WLk+1 to WLn, second bit lines BLy1 to BLyj, and source lines SL1 to SLj. One end of each of the MTJ elements may be connected to the second bit lines BLy1 to BLyj, and the other end of each MTJ element may be connected to one end of the access transistor ATr. The other end of the access transistor ATr may be connected to the source lines SL1 to SLj, and the gate electrode of the access transistor ATr may be connected to the word lines WLk+1 to WLn. Memory cells of the second data cell array 1100b may be selected and accessed similarly to memory cells of the first data cell array 1100a. When the access transistor ATr is turned on by the word line voltage, the MTJ element is programmed in the parallel state P or anti-parallel state AP depending on the direction of the current applied through one of the second bit lines BLy and the source line SL. In one or more examples, the second bit lines BLy1 to BLyj may be formed using two metal layers located on top of the MTJ element.

A plurality of reference cells RC corresponding to one column included in the reference cell array 1200 may share a reference bit line R_BL and a reference source line R_SL. Additionally, the plurality of reference cells RC may be independently selected by the plurality of word lines WL1 to WLk and WLk+1 to WLn. Since the reference cell RCi selected by the word line (e.g., for WLi, ‘i’ may be a positive integer less than or equal to ‘n’) is in the same environment (e.g., the path along which the read current moves) as the memory cell MCi selected by the same word line WLi, the error for reading the value stored in the memory cell MCi can be reduced. Each of the plurality of reference cells RC may include an access transistor. Each of the plurality of reference cells RC may not include a magnetic tunnel junction MTJ element compared to the memory cell MC. For example, the reference bit line R_BL of the present embodiments can be formed using an unused floating metal layer located on top of the MTJ. For example, the reference bit line R_BL may be formed by connecting a metal layer located above the MTJ and a metal layer located below the MTJ.

According to the exemplary configuration of the data cell array and the reference cell array described above, the data cell array 1100 includes data cell arrays 1100a and 1100b divided according to the first bit line BLx and the second bit line BLy. Accordingly, as the number of memory cells connected to each of the bit lines BLx and BLy decreases, leakage current occurring during the read operation can be reduced, thereby increasing the read margin. In one or more examples, the reference bit line R_BL of the reference cell array 1200 may be formed using an unused floating metal layer located on top of the magnetic tunnel junction MTJ. The metal resistance of the reference cell can be reduced through the reference bit line R_BL structure in which two metal layers are connected in parallel. The problem of load matching between the reference cell and data cell due to the relatively large metal resistance can be resolved.

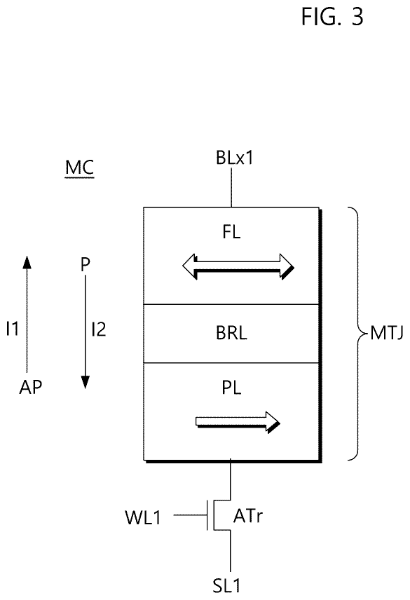

FIG. 3 is a diagram showing how data is written into the memory cell MC of FIG. 2, according to one or more embodiments. Referring to FIG. 3, the memory cell may include an access transistor ATr and an MTJ element that are activated by the word line WL1.

The MTJ element may include a free layer FL, a barrier layer BRL, and a pinned layer PL. The barrier layer BRL is located between the free layer FL and the pinned layer PL, the free layer FL may be connected to the first bit line BLx1, and the pinned layer PL may be connected to the other end of the access transistor ATr.

The magnetization direction of the pinned layer PL may be fixed to a specific direction, and the magnetization direction of the free layer FL may change depending on specific conditions (e.g., direction of writing current). Depending on the embodiment, the MTJ element may further include an anti-ferromagnetic layer to fix the magnetization direction of the pinned layer PL.

In one or more examples, the free layer FL may include a material having a changeable magnetization direction. In one or more examples, the magnetization of free layer FL may switch in two directions. For example, due to the spin Hall effect, spin current is generated HM in a non-magnetic heavy metal (HM) layer, which diffuses into the MTJ's free layer and exerts a spin-orbit torque on the magnetization of the free layer. Under the right conditions, this torque can induce a switching of magnetization depending on the direction of the current within the channel. The magnetization direction of the free layer FL may be changed by electrical/magnetic factors provided outside and/or inside the memory cell MC. The free layer FL may include a ferromagnetic material including at least one of cobalt (Co), iron (Fe), and nickel (Ni). For example, the free layer FL may include at least one of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO and Y₃Fe₅O₁₂. However, the scope of the present disclosure is not limited to these materials.

In one or more examples, the thickness of the barrier layer BRL may be thinner than the spin diffusion distance. The barrier layer BRL may include a non-magnetic material. For example, the barrier layer BRL may include at least one of magnesium (Mg), titanium (Ti), aluminum (Al), magnesium-zinc (MgZn), oxide of magnesium-boron (MgB), and titanium (Ti) and nitride of vanadium (V). However, the scope of the present disclosure is not limited thereto.

In one or more examples, the pinned layer PL may have a magnetization direction fixed by the antiferromagnetic layer. The pinned layer PL may include a ferromagnetic material. For example, the pinned layer PL may include at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO and Y₃Fe₅O₁₂. Depending on the embodiment, the antiferromagnetic layer may include an anti-ferromagnetic material. For example, the antiferromagnetic layer may include at least one of PtMn, IrMn, MnO, MnS, MnTe, MnF₂, FeCl₂, FeO, CoCl₂, CoO, NiCl₂, NiO, and Cr. However, the scope of the present embodiments is not limited thereto.

The magnetization direction of the free layer FL may change depending on the direction of the write currents I1 and I2 flowing through the MTJ element. For example, when a current flows from the source line SL1 to the bit line BLx1, such as the first write current I1, the magnetization direction of the free layer FL is opposite to the magnetization direction of the pinned layer PL, and this state may be an anti-parallel state AP. On the contrary, when the current flows from the bit line BLx1 to the source line SL1, such as the second write current I2, the magnetization direction of the free layer FL is the same as the magnetization direction of the pinned layer PL, where this state may be a parallel state P.

When the MTJ element is in the anti-parallel state AP, the MTJ element may have an anti-parallel resistance Rap. When the MTJ element is in the parallel state P, the MTJ element may have a parallel resistance Rp. In some embodiments, the memory device 1000 may store the first data DO or the second data D1 using the size of the resistance value of the MTJ element. For example, when the MTJ element is in the parallel state P with a relatively small resistance value, logic ‘0’ or first data DO may be considered programmed. In one or more examples, when the MTJ element is in the anti-parallel state AP with a relatively large resistance value, logic ‘1’ or the second data D1 may be considered programmed.

The memory device 1000 may perform the read operation through comparison with a reference resistor Rref having an intermediate magnitude between the first data DO and the second data D1. In the present embodiments, the reference resistor Rref can be adjusted according to write data rather than using a fixed value. The reference resistor Rref can be determined through a test operation. Data can be stored in the memory cell MC according to the resistance value setting of the MTJ element, and data stored in the memory cell MC can be sensed by reading the resistance value of the MTJ element.

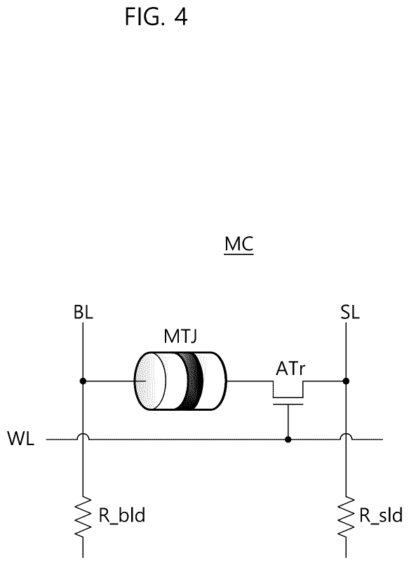

FIG. 4 is a diagram showing the configuration and connection relationship of memory cells included in a data cell array, according to one or more embodiments. Referring to FIG. 4, the memory cell includes an MTJ element and an access transistor ATr.

In one or more examples, the free layer FL of the MTJ element may be connected to the bit line BL, and the pinned layer PL may be connected to the access transistor ATr. For example, during a write operation of logic ‘0’, when the word line WL may be activated, the access transistor ATr is turned on. At this time, a write current corresponding to logic ‘0’ is supplied through the bit line BL. Then, the MTJ element can be programmed to the parallel state P. During a read operation, data stored in a memory cell is sensed through detection of a current that varies depending on the resistance state of the selected memory cell.

Although the number of word lines may be increased to increase memory capacity, the resistance of the bit line BL may increase. In one or more examples, as the number of word lines increases, the amount of leakage current generated from unselected memory cells during the read operation also increases as the number of word lines increases. As the magnitude of the leakage current increases, the read margin for the selected memory cell rapidly decreases.

According to the present embodiments, by providing two or more bit lines (e.g., BLx, BLy) connected along the word line, the amount of leakage current occurring in the bit lines can be advantageously reduced. Accordingly, as the number of memory cells connected to each of the bit lines BLx and BLy decreases, leakage current occurring during the read operation can be advantageously reduced, which results in an improvement in read margin.

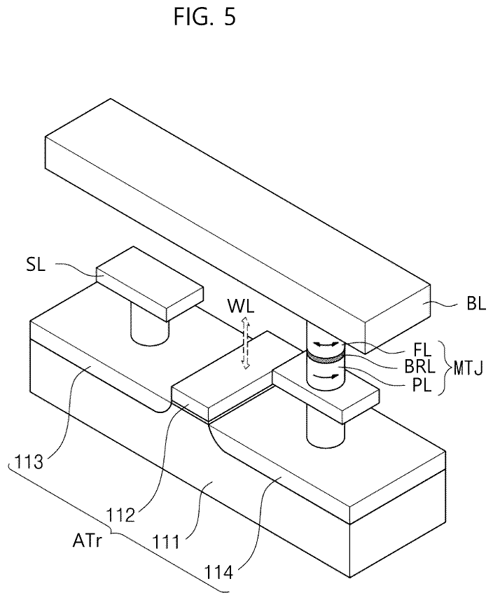

FIG. 5 is a diagram showing the structure of the memory cell shown in FIG. 4, according to one or more embodiments. Referring to FIG. 5, the memory cell MC may include an access transistor ATr, a bit line BL, a word line WL, a source line SL, and MTJ elements.

The access transistor ATr may include a body substrate 111, a gate electrode 112, and junctions 113 and 114. The junction 113 may be formed on the body substrate 111 and may be connected to the source line SL. The junction 114 may be formed on the body substrate 111 and may be connected to the bit line BL through an MTJ element. The gate electrode 112 may be formed on the body substrate 111 between the junctions 113 and 114 and may be connected to the word line WL.

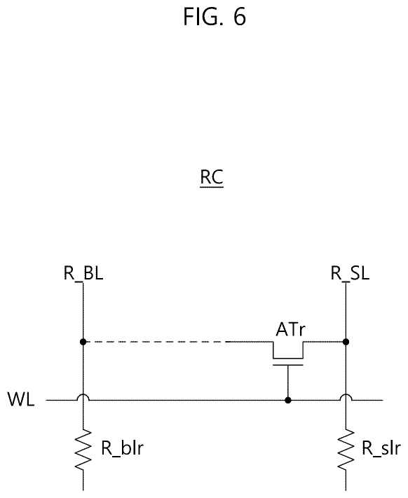

FIG. 6 is a diagram briefly showing the circuit structure of a reference cell, according to one or more embodiments. Referring to FIG. 6, the reference cell RC may include an access transistor ATr connected to the reference bit line R_BL and the reference source line R_SL.

The reference bit line R_BL and the reference source line R_SL may be electrically short-circuited or open by the access transistor ATr of the reference cell RC. As such, a reference cell RC without a variable resistance element such as MTJ may be referred to as a shorted cell. In order to compensate for the voltage drop due to the bit line or source line connected to the memory cell MC, the reference cell RC connected to the reference bit line R_BL and the reference source line R_SL is placed to the reference cell array 1200.

The reference bit line R_BL connected to the reference cell RC may be formed using a metal line located in the lower layer of the MTJ element in the cell array. In one or more examples, the bit line of the memory cell MC may be formed using a metal line located on the upper layer of the MTJ element. Accordingly, it is not easy to match the resistance of the bit line of the memory cell MC and the resistance R_blr of the reference bit line R_BL. Additionally, as the number of word lines increases to increase memory capacity, such load matching becomes more difficult. The reference bit line R_BL connected to the reference cell RC of the present embodiments solves this problem by electrically connecting the lower metal layer of the MTJ element and the unused floating bit line at the top of the MTJ element. According to the present embodiments, the resistance R_blr of the reference bit line R_BL can be reduced by connecting the bit lines located in two metal layers at the edges of the reference cell array 1200.

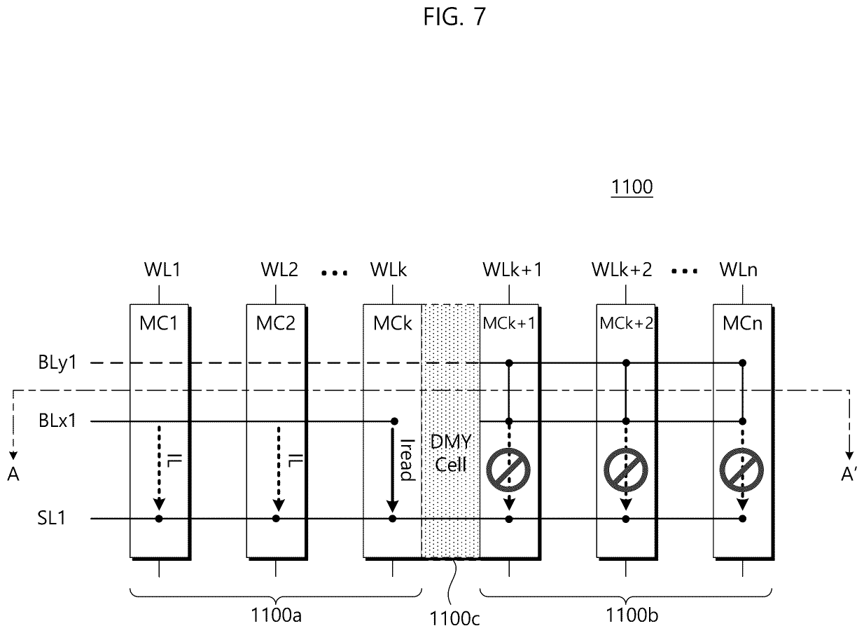

FIG. 7 is a block diagram showing a method of connecting the first bit line BLx and the second bit line BLy of the first and second data cell arrays shown in FIG. 1. Referring to FIG. 7, a portion of the bit line structure of memory cells corresponding to one column of the data cell array 1100 is shown.

The data cell array 1100 may be divided into a first data cell array 1100a and a second data cell array 1100b according to word lines WL1 to WLk and WLk+1 to WLn. A dummy cell 1100c may be formed between the first data cell array 1100a and the second data cell array 1100b. In one or more examples, the dummy cell 1100c is a dummy structure inserted between the first data cell array 1100a and the second data cell array 1100b to form bit lines BLx1 and BLy1 using different metal layers. In one or more examples, the dummy cell 1100c is not used for storing data, and may be used provided spacing between one or more word lines or one or more bit lines.

Memory cells MCi to MCk included in the first data cell array 100a may be respectively connected to word lines WL1 to WLk. The memory cells MCk+1 to MCn included in the second data cell array 1100b are connected to word lines WLk+1 to WLn. Read and write operations of the memory cells MCi to MCk are performed through the first bit line BLx1 and the source line SL1. Read and write operations of the memory cells MCk+1 to MCn included in the second data cell array 1100b are performed through the second bit line BLy1 and the source line SL1.

The first bit line BLx1 may be connected to the memory cells MCi to MCk of the first data cell array 1100a using one metal layer. The bit lines formed in the data cell array 1100 may be formed using metal lines formed on top of the MTJ element. In one or more examples, let us assume that two metal layers among the upper metal lines of the MTJ element are used for bit lines. Then, the first bit line BLx1 may be formed using the first metal line located at the lower part of the upper metal lines of the MTJ element. The first bit line BLx1 may be connected to the memory cells MCi to MCk through the first metal line. The first bit line BLx1 no longer extends beyond the dummy cell 1100c. For example, the first bitline BLx1 may be electrically blocked from the memory cells MCk+1 to MCn included in the second data cell array 1100b.

In one or more examples, the second bit line BLy1 is bypassed in the area of the first data cell array 1100a using one metal layer without being electrically connected to the memory cells MCi to MCk. For example, the second bit line BLy1 may be formed using a second metal line that is not used as the first bit line BLx1 among the upper metal lines of the MTJ element. The second metal line may be a metal layer formed above the first metal line. The second bit line BLy1 may be connected to the memory cells MCk+1 to MCn in the second data cell array 1100b area using two metal layers. For example, the second bit line BLy1 may be formed using both the lower first metal line and the upper second metal line in the area of the second data cell array 1100b based on the dummy cell 1100c. The method of forming the source line SL1 can be applied in the same way to the first data cell array 1100a and the second data cell array 1100b.

When the memory cell MCk of the first data cell array 1100a is selected for the read operation, the word line WLk may be selected and the access transistor ATr may be turned on. As the access transistor ATr is turned on, a read current Iread corresponding to the resistance state of the MTJ element of the memory cell MCk flows from the first bit line BLx1 to the source line SL1. In addition, leakage current IL may flow through each of the unselected memory cells MCi to MCk−1 in the first data cell array 1100a. However, during the read operation of the memory cell MCk, the memory cells MCk+1 to MCn of the second data cell array 1100b do not have an electrical connection with the first bit line BLx1 driven for sensing. Accordingly, leakage current (e.g., off-cell leakage) occurring in unselected memory cells during the read operation is advantageously limited to the first data cell array 1100a. As a result, even if the number of word lines is increased, the leakage current (e.g., off-cell leakage) of unselected memory cells can be reduced. Therefore, this indicates that it is possible to secure a read margin even if the number of word lines is increased to increase the memory capacity of the resistive memory device 1000.

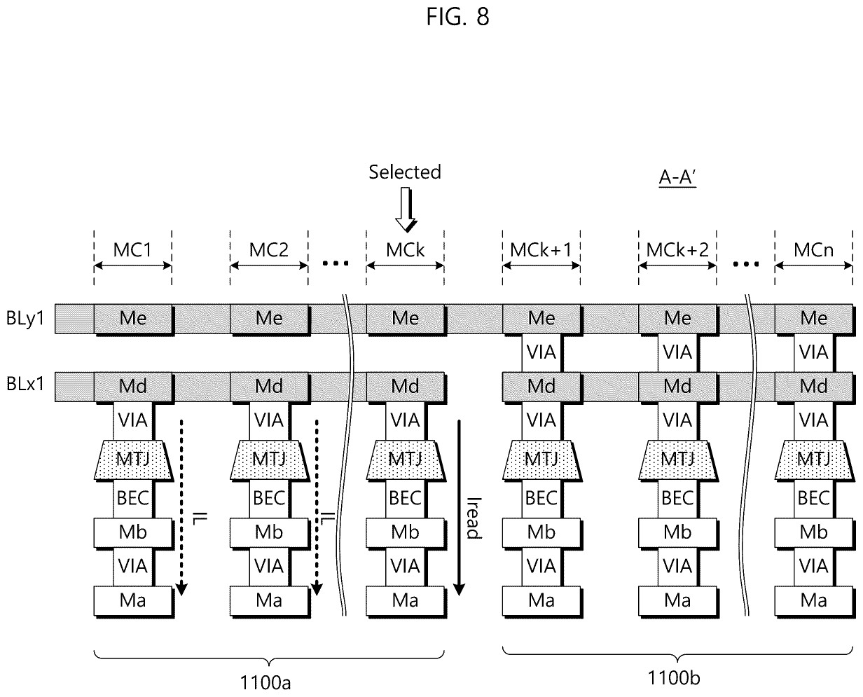

FIG. 8 is a cross-sectional view briefly showing a cross-section of the data cell array taken along the cutting line A-A′ of FIG. 7. Referring to FIG. 8, the memory cells MCi to MCn of the first data cell array 1100a and the second data cell array 1100b are driven by the first and second bit lines BLx1 and BLy1 that are electrically separated.

The bit lines and source lines of the memory cells MCi to MCn may be formed through the upper metal layers (Me, Md) of the MTJ element and the lower metal layers (Ma, Mb) of the MTJ element. A lower electrode contact BEC and a via are used to connect the lower metal layers (Ma, Mb) of the MTJ element. In particular, in order to form the separated bit line structures BLx1 and BLy1 of the present embodiments, the first bit line BLx1 connected to the memory cells MC1 to MCk may be connected to the MTJ elements using the metal layer Md. Accordingly, in the first data cell array 1100a area, the via VIA may be removed between the metal layer Md forming the first bit line BLx1 and the metal layer Me forming the second bit line BLy1.

In the second data cell array 1100b area, the second bit line BLy1 may be formed using two metal layers Md and Me. For example, the second bit line BLy1 bypassed in the first data cell array 1100a area may be connected to the metal layer Md through the via VIA in the second data cell array 1100b area.

In one or more examples, memory cells MCi to MCk may be included in the first data cell array 1100a, and memory cells MCk+1 to MCn may be included in the second data cell array 1100b. Access to the memory cells MCi to MCk may be achieved through the first bit line BLx1 and the source line. Access to the memory cells MCk+1 to MCn included in the second data cell array 1100b is achieved through the second bit line BLy1 and the source line SL1.

The first bit line BLx1 may be connected to the memory cells MCi to MCk of the first data cell array 1100a using one metal layer Md. Since the bit lines of the memory cells MC may be connected to the MTJ element, these bit liens may be formed using metal layers (Md, Me) located on top of the MTJ element. Accordingly, the memory cells MCi to MCk of the first data cell array 1100a may be formed using the metal layer Md located at the lower part of the metal layers Md and Me. The first bit line BLx1 formed of a metal line corresponding to the metal layer Md no longer extends into the second data cell array 1100b area. Accordingly, the first bit line BLx1 is electrically blocked from the memory cells MCk+1 to MCn included in the second data cell array 1100b.

In one or more examples, the second bit line BLy1 extends from the area of the first data cell array 1100a to the second data cell array 1100b using the upper metal layer Me. At this time, the second bit line BLy1 is bypassed without electrical connection with the memory cells MCi to MCk of the first data cell array 1100a located below. For example, the second bit line BLy1 may be formed using the metal layer Me that is not used as the first bit line BLx1 among the upper metal layers Md and Me of the MTJ element.

In particular, the second bit line BLy1 may be connected to the memory cells MCk+1 to MCn in the area of the second data cell array 1100b using both metal layers Md and Me. For example, the second bit line BLy1 can be formed using both the first metal line corresponding to the lower metal layer Md and the second metal line corresponding to the upper metal layer Me in the area of the second data cell array 1100b. The method of forming the source line SL1 can be applied in the same way to the first data cell array 1100a and the second data cell array 1100b.

In one or more examples, when the memory cell MCk of the first data cell array 1100a is selected for the read operation, the word line WLk may be activated and the access transistor ATr is turned on. Then, the read current Iread corresponding to the resistance state of the MTJ element of the memory cell MCk flows from the first bit line BLx1 to the source line SL1. In one or more examples, leakage current IL may flow through each of the unselected memory cells MCi to MCk−1 in the first data cell array 1100a.

During the read operation of the memory cell MCk, the memory cells MCk+1 to MCn of the second data cell array 1100b do not have an electrical connection with the first bit line BLx1. Accordingly, during the read operation of the memory cell MCk, the leakage current IL through the second bit line BLy1 can be ignored. It can be seen that by configuring the bit lines of memory cells in this way, the leakage current (off-cell leakage) of unselected memory cells can be greatly reduced even if the number of word lines is increased to increase memory capacity. For example, even if the number of word lines of the resistive memory device 1000 is greatly increased to increase memory capacity, the influence of leakage current occurring in unselected memory cells can be advantageously reduced, resulting in securing the read margin of the high-capacity resistive memory device 1000.

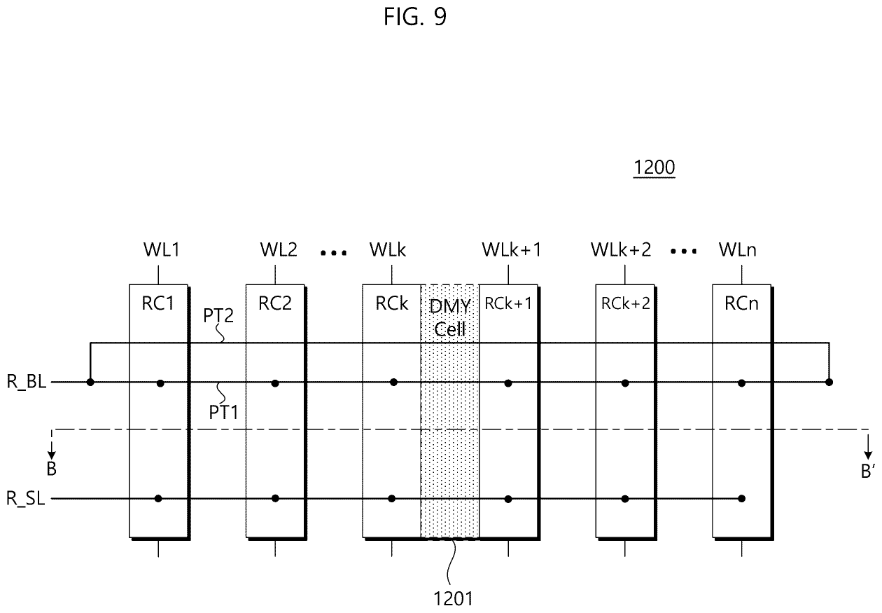

FIG. 9 is a block diagram showing a method of connecting the reference bit line R_BL and the reference source line R_SL of the reference cell array shown in FIG. 1, according to one or more embodiments. Referring to FIG. 9, a portion of the reference bit line R_BL structure of memory cells corresponding to one column of the reference cell array 1200 is shown.

Unlike the data cell array 1100, the reference bit line of the reference cell array 1200 does not vary according to the word lines (WL1 to WLk, WLk+1 to WLn) and has the same structure. In particular, the reference bit line R_BL using two metal layers can provide a clue to solving the problem of load matching with data cells due to increased resistance of the bit line. In one or more examples, the dummy cell 1201 may be provided with substantially the same structure as the dummy cell formed in the data cell array 1100.

The reference bit line R_BL may include a first path PT1 and a second path PT2. Current may be supplied to the reference cell connected to the activated word line through a reference bit line R_BL of a parallel structure having the first path PT1 and the second path PT2. For example, the first path PT1 may be formed using metal layers or metal lines located below the MTJ element. The second path PT2 may be formed through a floating reference bit line that is not used in the reference cell array 1200 at the top of the MTJ element. Additionally, the connection between the first path PT1 and the second path PT2 can be implemented using vias and metal layers on the outside of the reference cell array 1200.

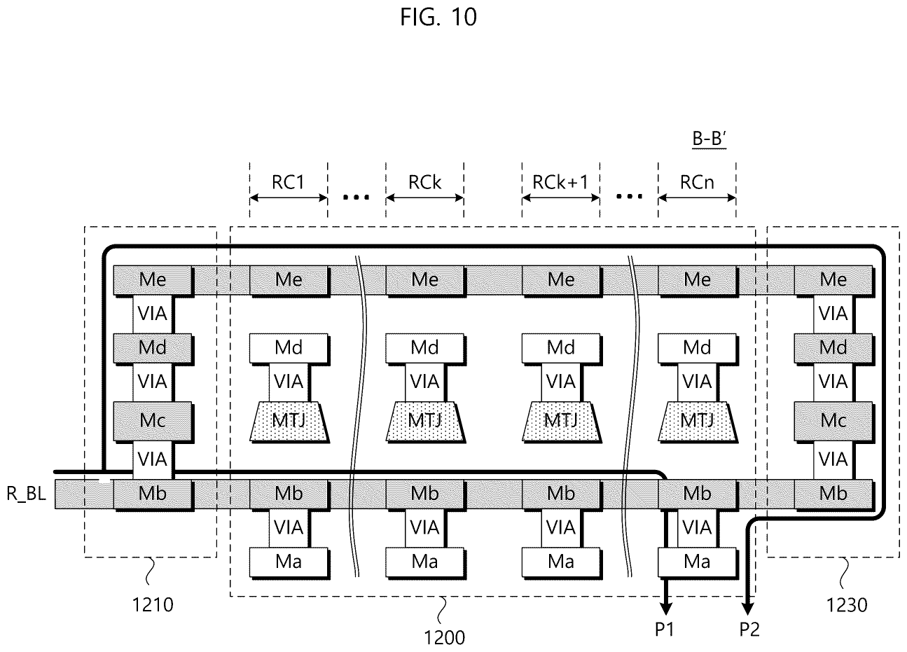

FIG. 10 is a cross-sectional view briefly showing a cross-section of the reference cell array taken along the cutting line A-A′ of FIG. 9. Referring to FIG. 10, the reference bit line R_BL may be formed through the metal layer Mb located at the bottom of the MTJ element and the upper metal layer Me of the MTJ element. The upper metal layer Me of the MTJ element corresponds to a floating metal layer that is generally not used in the reference cell array 1200. The metal lines formed within the reference cell array 1200 through the metal layers Mb and Me can be connected by using the metal layers Mc and Md and vias VIA of the edge regions 1210 and 1230 of the reference cell array 1200. In one or more examples, in each of the edge regions 1210 and 1230, connection structures for connecting the floating metal layer and the lower metal layer Mb of the MTJ element may be formed using vias or metal layers.

In one or more examples, when the reference cell RCn is selected for the read operation, the word line may be activated and the access transistor ATr is turned on. Then, the current flowing from the reference bit line R_BL of the reference cell RCn to the reference source line R_SL follows two paths P1 and P2. In other words, the current flows along the first path P1 formed using the metal layer Mb located at the bottom of the MTJ element and the second path P2 formed using the metal layer Me located at the top of the MTJ element. Accordingly, the resistance value of the entire reference bit line R_BL is reduced compared to the case where only one metal layer Mb is used. This reduction in the resistance value of the reference bit line R_BL enables improvement of actual load matching performance with the memory cell MC.

As explained above, the reference bit line R_BL of the reference cell array 1200 can be formed using an unused floating metal layer located on top of the MTJ element. The metal resistance of the reference cell can be reduced through the reference bit line R_BL structure in which two metal layers are connected in parallel. Accordingly, the problem of load matching between the reference cell and the data cell due to the relatively large metal resistance can be resolved.

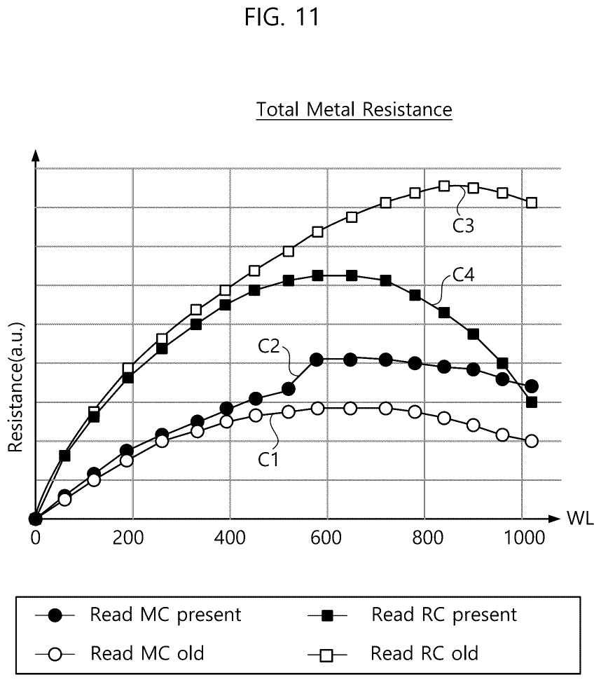

FIG. 11 is a graph showing the effect of the present embodiments. Referring to FIG. 11, when 1024 word lines are applied to increase memory capacity, curves C2 and C4 show the bit line resistance when the bit line structure of the present embodiments is applied, and curves C1 and C3 show the bit line resistance when a general bit line structure is applied.

Curve C1 shows the resistance value of a cell corresponding to a selected word line when the bit line of the data cell array 1100 may be formed using only one metal layer. Curve C2 shows the resistance value of cells for each word line when the bit line of the data cell array 1100 may be formed by dividing it into first bit lines BLx and second bit lines BLy.

Curve C3 shows the resistance value of the selected reference cell RC when forming a bit line using only one metal layer Mb in the reference cell array 1200. Curve C4 shows the cell resistance in the selected reference cell RC when the reference bit line R_BL is implemented using two metal layers using a floating reference bit line in the reference cell array 1200.

In a general cell array structure that does not use the bit line structure of the present embodiments described above, it can be seen that the difference in resistance between the memory cell MC and the reference cell RC increases as the number of word lines increases. In other words, it can be seen that the resistance or load mismatch of the curves C1 and C3 increases in proportion to the number of word lines. This increase in load mismatch between the memory cell MC and reference cell RC reduces the read margin and acts as a barrier to increasing memory capacity.

In one or more examples, in the cell array structure using the bit line structure of the present embodiments, it can be seen that the difference in resistance value between the memory cell MC and the reference cell RC increases in a certain section as the number of word lines increases, but then decreases again. In other words, it can be seen that the resistance or load mismatch of the curves C2 and C4 increases as the number of word lines increases and then decreases again. For example, according to the present embodiments, load mismatch between the memory cell MC and the reference cell RC can be reduced. Therefore, it can be seen that it is possible to secure a read margin even if the number of word lines is increased to increase memory capacity.

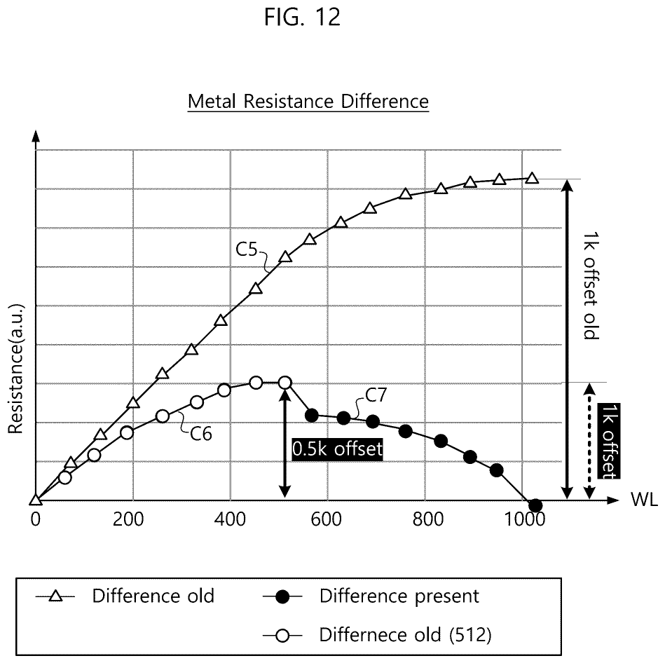

FIG. 12 shows the difference in resistance values between the memory cell MC and the reference cell RC of FIG. 11 when the present embodiments is applied and when the present embodiments is not applied. Referring to FIG. 12, it can be seen that even when increasing the capacity, the problem of resistance or load mismatch between the memory cell MC and the reference cell RC can be solved by using the bit line structure of the present embodiments.

Curve C5 shows the difference in resistance between the memory cell MC and the reference cell RC in a cell array structure that does not use the bit line structure of the present embodiments. In curve C5, as the number of word lines increases, the resistance or load mismatch between the memory cell MC and the reference cell RC continues to increase. Therefore, it can be seen that there is a limit to increasing the number of word lines as the load mismatch between the memory cell MC and the reference cell RC increases.

The curve C6 shows the difference in resistance between the memory cell MC and the reference cell RC when using the bit line structure of the present embodiments or in a general bit line structure using 512 word lines. In the present embodiments, the first data cell array 1100a in which 512 word lines may be formed uses only one metal layer to form bit lines. Therefore, the resistance difference may appear the same as that in a general bit line structure using 512 word lines.

The curve C7 following the curve C6 represents the difference in resistance between the memory cell MC and the reference cell RC in the second data cell array 1100b of the present embodiments that forms a bit line using two metal layers. It can be seen that the resistance mismatch between the memory cell MC and the reference cell RC can be dramatically reduced through the bit line structure of the second data cell array 1100b using the second bit lines BLy.

According to the present embodiments, load mismatch between the memory cell MC and the reference cell RC can be reduced. In particular, the amount of leakage current can be reduced by half through the data cell array 1100 divided into first bit lines BLx and second bit lines BLy. Therefore, the problems of leakage current and load mismatch between memory cells MC and reference cells RC, which act as barriers to increasing capacity, can be solved through the present embodiments.

The above are specific embodiments for carrying out the present embodiments. In addition to the above-described embodiments, the present embodiments may include simple design changes or easily changeable embodiments. In addition, the present embodiments will include techniques that can be easily modified and implemented using the embodiments. Therefore, the scope of the present embodiments should not be limited to the above-described embodiments, and should be defined by the claims and equivalents of the claims of the present embodiments as well as the claims to be described later.

What is claimed is:

1. A resistive memory device, comprising:
a data cell array comprising a plurality of memory cells, each column of the plurality of memory cells having an electrically separated first bit line and a second bit line;
a row decoder configured to decode a row address and select one or more word lines of the plurality of memory cells in response to the row address; and
a column decoder configured to decode a column address and select one of the first bit line and the second bit line in response to the row address decoded by the row decoder and the column address,
wherein the first bit line comprises a first metal layer, and the second bit line comprises the first metal layer and a second metal layer.

2. The resistive memory device of claim 1, wherein the data cell array comprises:
a first data cell array comprising one or more memory cells from the plurality of memory cells connected to the first bit line; and
a second data cell array comprising one or more memory cells from the plurality of memory cells connected to the second bit line.

3. The resistive memory device of claim 2, wherein a first distance between the first data cell array and the column decoder is less than a second distance between the second data cell array and the column decoder.

4. The resistive memory device of claim 3, wherein the second bit line comprises the second metal layer in an area of the first data cell array.

5. The resistive memory device of claim 4, wherein the second bit line comprises a via connecting the first metal layer and the second metal layer in an area of the second data cell array.

6. The resistive memory device of claim 2, wherein at least one of the first metal layer and the second metal layer is located on top of a magnetic tunnel junction element.

7. The resistive memory device of claim 6, wherein the second metal layer is located on top of the first metal layer.

8. The resistive memory device of claim 2, wherein a dummy cell is between the first data cell array and the second data cell array to separate an array area.

9. The resistive memory device of claim 1, further comprising:
a reference cell array sharing a word line with the data cell array,
wherein the reference cell array comprises a reference bit line connecting a lower metal layer of a magnetic tunnel junction and an upper metal layer of the magnetic tunnel junction.

10. The resistive memory device of claim 9, wherein the reference bit line comprises:
a first metal line located above the magnetic tunnel junction in the reference cell array;
a second metal line located below the magnetic tunnel junction;
a first connection structure comprising at least one via and a first metal layer connected through the first metal line and the second metal line; and
a second connection structure comprising at least one via and a second metal layer connected through the first metal line and the second metal line.

11. The resistive memory device of claim 10, wherein the first connection structure is at a first edge of the reference cell array, and the second connection structure is at a second edge of the reference cell array.

12. A resistive memory device, comprising:
a data cell array comprising a plurality of memory cells connected to one or more word lines;
a reference cell array sharing the one or more word lines with the data cell array;
a row decoder configured to decode a row address and select one of the one or more word lines in response to the row address; and
a column decoder configured to decode a column address and select a data bit line of the data cell array and a reference bit line of the reference cell array in response to the column address,
wherein the reference bit line comprises a lower metal layer of a magnetic tunnel junction and an upper metal layer of the magnetic tunnel junction.

13. The resistive memory device of claim 12, wherein the reference bit line comprises:
a first metal line on the magnetic tunnel junction in the reference cell array; and
a second metal line below the magnetic tunnel junction.

14. The resistive memory device of claim 13, wherein the magnetic tunnel junction is electrically separated from the first metal line and the second metal line.

15. The resistive memory device of claim 13, wherein the reference bit line comprises:
a first connection structure that penetrates and connects the first metal line and the second metal line; and
a second connection structure that penetrates and connects the first metal line and the second metal line.

16. The resistive memory device of claim 15, wherein the first connection structure is at a first edge of the reference cell array, and the second connection structure is at a second edge of the reference cell array.

17. The resistive memory device of claim 16, wherein the first connection structure or the second connection structure comprises at least one via and at least one metal layer.

18. The resistive memory device of claim 12, wherein the data cell array comprises a plurality of memory cells, and
wherein the data cell array comprises a first bit line and a second bit line that are electrically separated from each column of the plurality of memory cells.

19. The resistive memory device of claim 18, wherein the first bit line comprises a first metal layer, and the second bit line comprises the first metal layer and a second metal layer.

20. A resistive memory device, comprising:
a first data cell array connected to a first word line group and a first bit line group;
a second data cell array connected to a second word line group and a second bit line group, the second data cell array sharing a column with the first data cell array;
a reference cell array connected to the first word line group and the second word line group;
a row decoder configured to decode a row address and select a word line of the first word line group and the second word line group in response to the row address; and
a column decoder configured to decode a column address and select a bit line from one of the first bit line group and the second bit line group in response to the row address and the column address,
wherein the column decoder selects the first bit line group based on the row address corresponding to the first word line group, and selects the second bit line group based on the row address corresponding to the second word line group.
